(19) United States
(12) Patent Application Publication
(10) Pub. No.: US 2025/0218917 A1
(43) Pub. Date: Jul. 3, 2025

(54) DISPLAY DEVICE

(71) Applicant: LG Display Co., Ltd., Seoul (KR)

(72) Inventors: Jun HEO, Paju-si (KR); Rakhee PARK, Changwon-si (KR)

(21) Appl. No.: 18/775,060

(22) Filed: Jul. 17, 2024

(30) Foreign Application Priority Data
Dec. 29, 2023 (KR) 10-2023-0197283

(51) Int. Cl. H01L 23/498; H05K 1/11; H10K 59/131; H10K 59/90

(52) U.S. Cl. CPC H01L 23/49838; H05K 1/117; H10K 59/131; H10K 59/90; H05K 2201/09409

(57) ABSTRACT

Disclosed is a display device in which a gap size between bonding pads disposed on a circuit film is increased even though the number of signal lines for driving high-resolution and high-frequency display and the number of power lines for low-speed operation increase. The display device includes a display panel; a printed circuit board; and a circuit film disposed between and connected to the display panel and the printed circuit board, wherein the circuit film includes an input side bonding area connected to the printed circuit board and an output side bonding area connected to the display panel, wherein the input side bonding area includes a plurality of input pads connected to the output side bonding area, wherein the plurality of input pads are arranged in two rows.

### CROSS-REFERENCE TO RELATED APPLICATION

This application claims priority from Korean Patent Application No. 10-2023-0197283 filed on Dec. 29, 2023, in the Korean Intellectual Property Office, and all the benefits accruing therefrom under 35 U.S.C. 119, the contents of which in its entirety are herein incorporated by reference.

### BACKGROUND

### Technical Field

The present disclosure relates to a display device.

### Description of the Related Art

As the information society develops and various portable electronic devices such as mobile communication terminals and laptop computers develop, the demand for display devices applicable thereto is gradually increasing.

The display devices include liquid crystal display devices (LCD) using liquid crystals and OLED display devices using organic light emitting diodes (OLED).

### BRIEF SUMMARY

An embodiment of the present disclosure provides a display device in which the gap size between the bonding pads disposed on the circuit film is increased even though the number of signal lines for driving the high-resolution and high-frequency display and the number of power lines for low-speed operation increase.

Furthermore, an embodiment of the present disclosure provides a display device in which input and output pads directly connected to each other among the bonding pads of the circuit film are arranged in two rows to increase the gap size between the bonding pads.

Technical features according to the present disclosure are not limited to those mentioned above. Other technical features and improvements according to the present disclosure that are not mentioned may be understood based on following descriptions, and may be more clearly understood based on embodiments according to the present disclosure. Further, it will be easily understood that the features and improvements according to the present disclosure may be realized using means shown in the claims or combinations thereof.

A display device according to one aspect of the present disclosure may include a display panel; a printed circuit board; and a circuit film disposed between and connected to the display panel and the printed circuit board, wherein the circuit film includes an input side bonding area connected to the printed circuit board and an output side bonding area connected to the display panel, wherein the input side bonding area includes a plurality of input pads connected to the output side bonding area, wherein the plurality of input pads are arranged in two rows.

A display device according to another aspect of the present disclosure may include a printed circuit board including a pad for outputting a plurality of voltages and a plurality of control signals; a display panel including a display area and a non-display area around the display area, wherein a plurality of sub-pixels are disposed in the display area, and a pad is disposed in the non-display area; a circuit film including an input side bonding area bonded to the pad of the printed circuit board and an output side bonding area bonded to the pad of the display panel, wherein the input side bonding area includes a plurality of input pads, wherein at least two of the plurality of input pads are respectively disposed in at least two rows; and a source driver mounted on the circuit film, wherein the source driver is electrically connected to the printed circuit board via the input side bonding area, and is electrically connected to the display panel via the output side bonding area.

According to embodiments of the present disclosure, the input and output pads directly connected to each other among the bonding pads of the circuit film are arranged in two rows to increase the gap size between the bonding pads, thereby realizing the display device that requires high-resolution and high-frequency display.

Furthermore, according to embodiments of the present disclosure, the gap between bonding pads may be increased without increasing a width of the circuit film.

Furthermore, according to embodiments of the present disclosure, an image quality in high-resolution and high-frequency display may be improved by increasing the gap between the bonding pads to reduce the interference therebetween.

Furthermore, according to embodiments of the present disclosure, the spacing between the bonding pads may be increased, thereby improving process capability.

According to embodiments of the present disclosure, production energy may be reduced by optimizing a process.

The effect of the present disclosure is not limited to the effects mentioned above, and other effects not mentioned will be clearly understood by those skilled in the art from the description below.

### BRIEF DESCRIPTION OF THE SEVERAL VIEWS OF THE DRAWINGS

FIG. 1 schematically shows a display device according to one embodiment of the present disclosure.

FIG. 2 shows a connection relationship of a circuit film in a display device according to an embodiment of the present disclosure.

FIG. 3 is a top view of a circuit film of a display device according to an embodiment of the present disclosure.

FIG. 4 is a cross-sectional view of one side of a circuit film in a display device according to an embodiment of the present disclosure.

FIG. 5 is a cross-sectional view of the other side of the circuit film in a display device according to an embodiment of the present disclosure.

FIG. 6 shows a bottom view and a top view for inspection of a bonding state of a circuit film in a display device according to an embodiment of the present disclosure.

### DETAILED DESCRIPTIONS

Advantages and features of the present disclosure, and a method of achieving the advantages and features will become apparent with reference to embodiments described later in detail together with the accompanying drawings. However, the present disclosure is not limited to the embodiments as disclosed under, but may be embodied in various different forms. Thus, these embodiments are set forth only to make the present disclosure complete, and to completely inform the scope of the present disclosure to those of ordinary skill in the technical field to which the present disclosure belongs.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure including the appended claims.

A shape, a size, a ratio, an angle, a number, etc., disclosed in the drawings for illustrating embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “comprising,” “include,” and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

It will be understood that when an element or layer is referred to as being “connected to,” or “connected to” another element or layer, it may be directly on, connected to, or combined to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate area, or the like is be disposed “on” or “on a top” of another layer, film, region, plate area, or the like, the former may directly contact the latter or still another layer, film, region, plate area, or the like may be disposed between the former and the latter. As used herein, when a layer, film, region, plate area, or the like is directly disposed “on” or “on a top” of another layer, film, region, plate area, or the like, the former directly contacts the latter and still another layer, film, region, plate area, or the like is not disposed between the former and the latter. Further, as used herein, when a layer, film, region, plate area, or the like is disposed “below” or “under” another layer, film, region, plate area, or the like, the former may directly contact the latter or still another layer, film, region, plate area, or the like may be disposed between the former and the latter. As used herein, when a layer, film, region, plate area, or the like is directly disposed “below” or “under” another layer, film, region, plate area, or the like, the former directly contacts the latter and still another layer, film, region, plate area, or the like is not disposed between the former and the latter.

In descriptions of temporal relationships, for example, temporal precedent relationships between two events such as “after,” “subsequent to,” “before,” etc., another event may occur therebetween unless “directly after,” “directly subsequent” or “directly before” is indicated.

When a certain embodiment may be embodied differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first,” “second,” “third,” and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

Spatially relative terms, such as “beneath,” “below,” “lower,” “under,” “above,” “upper,” and the like, may be used herein for ease of explanation to describe one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented for example, rotated 90 degrees or at other orientations, and the spatially relative descriptors used herein should be interpreted accordingly.

The features of the various embodiments of the present disclosure may be partially or entirely combined with each other, and may be technically associated with each other or operate with each other. The embodiments may be embodied independently of each other and may be embodied together in an association relationship.

In interpreting a numerical value, the value is interpreted as including an error range unless there is separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects,” and the like should not be construed such that any aspect or design as described is superior to or advantageous over other aspects or designs.

Further, the term “or” means “inclusive or” rather than “exclusive or.” That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

In description of flow of a signal, for example, when a signal is delivered from a node A to a node B, this may include a case where the signal is transferred from the node A to the node B via another node unless a phrase ‘immediately transferred’ or ‘directly transferred’ is used.

Hereinafter, a display device according to each of embodiments of the present disclosure will be described with reference to the attached drawings.

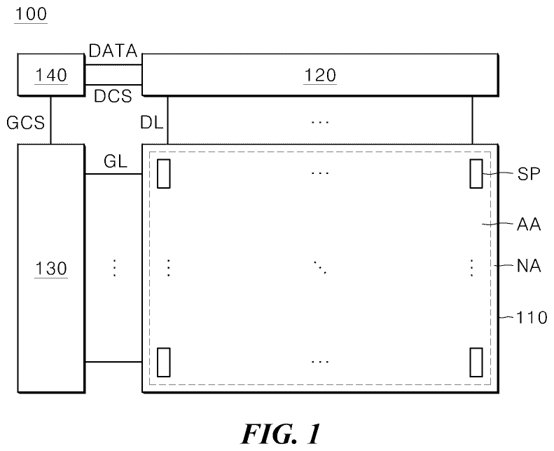

FIG. 1 schematically shows a display device according to one embodiment of the present disclosure.

Referring to FIG. 1, a display device 100 according to embodiments of the present disclosure may include a display panel 110, a data driving circuit 120, and a timing controller 140.

In the display panel 110, signal lines such as a plurality of data lines DL and a plurality of gate lines GL may be disposed on a substrate. A plurality of sub-pixels SP may be disposed in the display panel 110 and may be electrically connected to the plurality of data lines DL and the plurality of gate lines GL.

The display panel 110 may include a display area AA where images are displayed and a non-display area NA where images are not displayed. A plurality of sub-pixels SP for displaying the image may be disposed in the display area AA, and a pad connected to a data driving circuit 120 or a gate driving circuit 130 may be disposed in the non-display area NA. In one example, the gate driving circuit 130 may be disposed on each of both opposing sides of the non-display area NA of the display panel.

The sub-pixels may include a plurality of red sub-pixels to emit red light, a plurality of green sub-pixels to emit green light, and a plurality of blue sub-pixels to emit blue light. To improve luminance, a plurality of white sub-pixels may be included therein. Each sub-pixel may include a light-emitting element and a driving circuit for driving the light-emitting element. In one example, the light-emitting element may be an organic light emitting diode.

The data driving circuit 120 may be a circuit configured to drive the plurality of data lines DL, to convert image data DATA received from the timing controller 140 into a data voltage, and to provide the data voltage to the plurality of data lines DL.

The data driving circuit 120 may include one or more source driver (SDIC: Source Driver Integrated Circuit). Each source driver SDIC may be connected to the display panel 110 using TAB (Tape Automated Bonding), may be connected to a bonding pad of the display panel 110 using COG (Chip On Glass), or may be implemented in a COF (Chip On Film) manner and may be electrically connected to the display panel 110.

The gate driving circuit 130 may be a circuit configured to drive the plurality of gate lines GL, and to provide a gate signal (referred to as a scan signal) to the plurality of gate lines GL.

The gate driving circuit 130 may output a gate signal of a turn-on level voltage or a gate signal of a turn-off level voltage under control of the timing controller 140. The gate driving circuit 130 sequentially outputs the gate signal of the turn-on level voltage to the plurality of gate lines GL to sequentially drive the plurality of gate lines GL.

The gate driving circuit 130 may be disposed on or connected to the substrate of the display panel 110. When the gate driving circuit 130 is embodied in a gate-in-panel (GIP) manner, the gate driving circuit may be disposed in the non-display area NA of the substrate.

The timing controller 140 may provide the image data DATA and a data control signal DCS to the data driving circuit 120. Furthermore, the timing controller 140 may provide a gate control signal GCS to the gate driving circuit 130.

The timing controller 140 may be configured to start scanning according to a timing implemented in each frame, convert the image data input from an external source so as to comply with a data signal format used by the data driving circuit 120, provide the converted image data DATA to the data driving circuit 120, and to control a data driving time according to a scan.

The timing controller 140 may receive, from a host system, various timing signals including a vertical synchronization signal Vsync, a horizontal synchronization signal Hsync, a data enable signal DE, and a clock signal CLK along with input image data.

In order to control the data driving circuit 120 and the gate driving circuit 130, the timing controller 140 may receive the timing signals including the vertical synchronization signal Vsync, the horizontal synchronization signal Hsync, an input data enable signal DE, and a clock signal CLK, generate the data control signal DCS and the gate control signal GC based on the received timing signals, and provide the data control signal DCS and the gate control signal GC to the data driving circuit 120 and the gate driving circuit 130, respectively.

In one example, the data control signal DCS may include a source start pulse SSP, a source sampling clock SSC, etc. The gate control signal GCS may include a gate start pulse GSP, a gate shift clock GSC, and a gate output enable signal GOE.

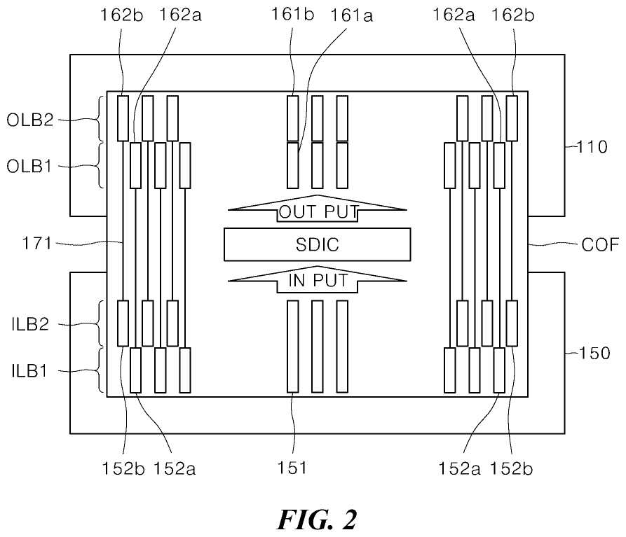

FIG. 2 shows a connection relationship of a circuit film in a display device according to an embodiment of the present disclosure.

Referring to FIG. 2, the display device according to an embodiment of the present disclosure may include the display panel 110, a circuit film COF connected to the display panel 110, and a printed circuit board 150 connected to the circuit film COF, and the source driver SDIC mounted on the circuit film COF.

FIG. 2 illustrates one circuit film COF for convenience of illustration. However, at least two circuit films COF may be connected to and disposed between the display panel 110 and the printed circuit board 150.

One end of the circuit film COF may be connected to the printed circuit board 150, and the other end thereof may be connected to the display panel 110. In this regard, one end of the circuit film COF connected to the printed circuit board 150 may be defined as an input side bonding area of the circuit film CO. The other end thereof connected to the display panel 110 may be defined as an output side bonding area of the circuit film COF.

The input side bonding area of the circuit film COF may be bonded to the pad (not shown) disposed on the printed circuit board 150. The printed circuit board 150 may be connected to the input side bonding area of one or more circuit films COF. For example, a plurality of circuit films may be connected to one printed circuit board 150.

The printed circuit board 150 may be a control printed circuit board or a source printed circuit board. The timing controller 140 and a power management circuit (not shown) may be mounted on the printed circuit board 150. The timing controller 140 may be electrically connected to the data driving circuit 120 and the gate driving circuit 130 via the printed circuit board 150 and the circuit film COF.

The input side bonding area of the circuit film COF may include a plurality of first input pads 152a, a plurality of second input pads 152b, and a plurality of third input pads 151. Each of the first input pad 152a, the second input pad 152b, and the third input pad 151 may be bonded to the pad on which the printed circuit board 150 is disposed.

The first input pads 152a may be arranged in a first row ILB1 of the input side bonding area of the circuit film COF, and the second input pads 152b may be arranged in a second row ILB2 of the input side bonding area of the circuit film COF. The third input pads 151 may be arranged in the first row ILB1 or the second row ILB2 thereof or in a single row as a combination of the first row ILB1 and the second row ILB2.

The first input pad 152a may be disposed in each of both opposing sides of the input side bonding area of the circuit film COF. The second input pad 152b may be disposed in each of both opposing sides of the input side bonding area of the circuit film COF. The plurality of first input pads 152a and the plurality of second input pads 152b may be directly and respectively connected to the plurality of first output pads 162a and the plurality of second output pads 162b of the output side bonding area of the circuit film COF via respective connection wirings 171 without connection to the source driver SDIC. In one example, the first input pad 152a may be directly connected to the first output pad 162a. Furthermore, the second input pad 152b may be directly connected to the second output pad 162b.

In this regard, a plurality of voltages and a plurality of control signals transmitted through the wirings of the printed circuit board 150 may be applied to the first input pad 152a and the second input pad 152b. For example, voltages applied to the sub-pixel SP of the display panel 110, voltages applied to the gate driving circuit 130, the gate control signal GCS, a GIP signal, the clock signal, a touch signal, etc., may be applied to the first input pad 152a and the second input pad 152b.

The third input pads 151 may be arranged in a single row as the combination of the first and second rows and may be disposed in a center of the input side bonding area. The third input pad 151 may be indirectly connected to the third output pad 161a and the fourth output pad 161b via the source driver SDIC.

In this regard, a digital signal may be applied to the third input pad 151. For example, the image data DATA, the data control signal DCS, and the clock signal for data sampling may be applied to the third input pad 151.

The output side bonding area of the circuit film COF may be bonded to the pad (not shown) disposed in the non-display area of the display panel 110. In one example, the circuit film COF may be bonded to the pad located on a front surface of the display panel 110 and may be bent toward a back surface of the display panel 110.

The output side bonding area of the circuit film COF may include a plurality of first output pads 162a, a plurality of second output pads 162b, a plurality of third output pads 161a, and a plurality of fourth output pads 161b. Each of the first output pad 162a, the second output pad 162b, the third output pad 161a and fourth output pad 161b may be bonded to the pad disposed in the non-display area of the display panel 110.

The first output pads 162a may be arranged in a first row OLB1 of the output side bonding area of the circuit film COF, and the second output pads 162b may be arranged in a second row OLB2 of the output side bonding area of the circuit film COF. The third output pads 161a may be arranged in the first row OLB1 of the output side bonding area of the circuit film COF. The fourth output pads 161b may be arranged in the second row OLB2 of the output side bonding area of the circuit film COF.

The first output pad 162a may be disposed in each of both opposing sides of the output side bonding area. The second output pad 162b may be disposed in each of both opposing sides of the output side bonding area. Each of the third output pad 161a and the fourth output pad 161b may be disposed in a center of the output side bonding area.

The first output pad 162a and the second output pad 162b may be directly and respectively connected to the first input pad 152a and the second input pad 152b in the input side bonding area of the circuit film COF via the respective connection wirings 171.

In one example, the first output pad 162a and the second output pad 162b may receive the voltages of the sub-pixel SP, the voltages of the gate driving circuit 130, the gate control signal GCS, the GIP signal, the clock signal, the touch signal, etc., from the first input pad 152a and the second input pad 152b, respectively.

Each of the first output pad 162a and the second output pad 162b may be bonded to the pad disposed in the non-display area of the display panel 110, and may transmit the voltages of the sub-pixel SP, the voltages of the gate driving circuit 130, the gate control signal GCS, the GIP signal, the clock signal, the touch signal, etc., to the display panel 110.

Furthermore, each of the third output pad 161a and the fourth output pad 161b may receive the data voltage corresponding to the image data DATA from the source driver SDIC. The third output pad 161a and the fourth output pad 161b may be bonded to the pad disposed in the non-display area of the display panel 110 and may output the data voltage corresponding to the image data DATA to the display panel 110.

The source driver SDIC may receive the image data DATA, the data control signal DCS, and the sampling clock signal via the third input pad 151, and may convert the image data DATA into the data voltage as an analog signal. Then, the source driver SDIC may provide the data voltage to the display panel 110 via the third output pad 161a and the fourth output pad 161b.

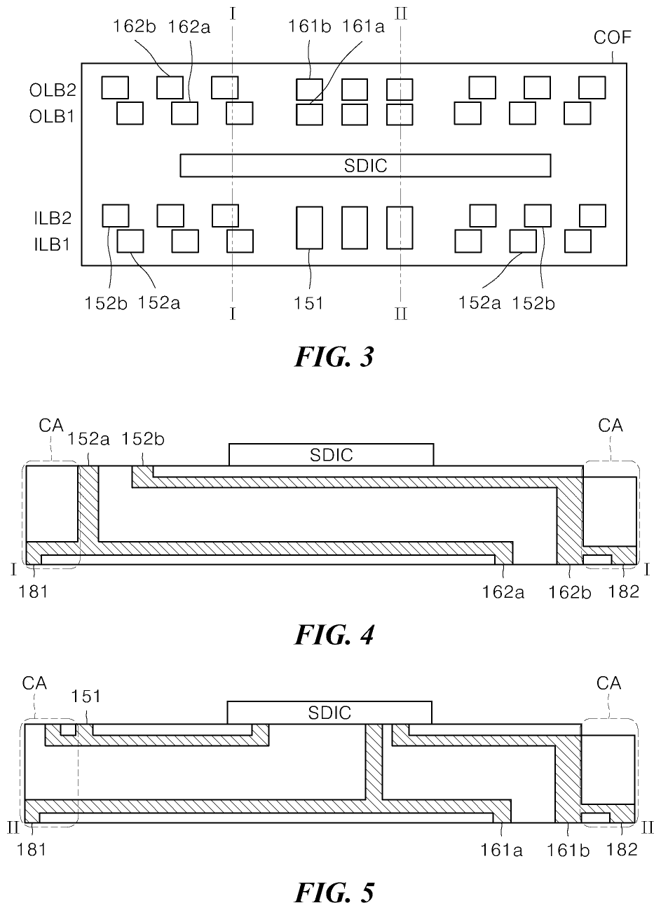

FIG. 3 is a top view of a circuit film of a display device according to an embodiment of the present disclosure.

Referring to FIG. 3, the source driver SDIC may be mounted on the circuit film COF. In one example, the source driver SDIC may be disposed on a center of the circuit film COF and may be mounted thereon in a chip-on-film manner.

The circuit film COF may include the first input pads 152a, the second input pads 152b, and the third input pads 151 connected to the printed circuit board 150.

The first input pads 152a may be arranged in the first row ILB1 of the input side bonding area, and the second input pads 152b may be arranged in the second row ILB2 of the input side bonding area. The first input pad 152a may be disposed in each of both opposing sides of the input side bonding area of the circuit film COF. The second input pad 152b may be disposed in each of both opposing sides of the input side bonding area of the circuit film COF. The third input pads 151 may be arranged in a single row as the combination of the first and second rows and may be disposed in a center of the input side bonding area.

In one example, the first input pads 152a and the second input pads 152b may be arranged in a staggered manner based on a reference line I. For example, the first input pads 152a may be disposed at a right side around the reference line I, and the second input pads 152b may be disposed at a left side around the reference line I.

Furthermore, the circuit film COF may include the plurality of first output pads 162a, the plurality of second output pads 162b, the plurality of third output pads 161a, and the plurality of fourth output pads 161b connected to the display panel 110.

The first output pads 162a may be arranged in the first row OLB1 of the output side bonding area of the circuit film COF, and the second output pads 162b may be arranged in the second row OLB2 of the output side bonding area of the circuit film COF. The first output pad 162a may be disposed in each of both opposing sides of the output side bonding area. The second output pad 162b may be disposed in each of both opposing sides of the output side bonding area.

In one example, the first output pads 162a and the second output pads 162b may be arranged in a zigzag or staggered pattern based on the reference line I. For example, the first output pads 162a may be disposed at the right side around the reference line I, and the second output pads 162b may be disposed at the left side around the reference line I.

Furthermore, the first input pads 152a and the first output pads 162a may be located in different layers, but may be arranged in the same column and directly connected to each other via the connection wirings, respectively. Furthermore, the second input pads 152b and the second output pads 162b may be located in different layers, but may be arranged along the same column and directly connected to each other via vias and connection wirings, respectively.

Each of the third output pad 161a and the fourth output pad 161b may be disposed in the center of the output side bonding area. In this regard, the third output pads 161a may be arranged in the first row OLB1 of the output side bonding area of the circuit film COF. The fourth output pads 161b may be arranged in the second row OLB2 of the output side bonding area of the circuit film COF.

In one example, third input pads 151 disposed at the center of the input side bonding area of the circuit film COF and the third output pads 161a and the fourth output pads 161b disposed at the center of the output side bonding area of the circuit film COF may be arranged along the same column. The third input pads 151 and the third output pads 161a and the fourth output pads 161b may be indirectly connected to each other via the source driver SDIC.

The source driver SDIC may receive the image data DATA via the third input pads 151. The source driver SDIC may convert the image data DATA into the data voltage and output the data voltage to the third output pad 161a and the fourth output pad 161b.

FIG. 4 is a cross-sectional view of one side of a circuit film in a display device according to an embodiment of the present disclosure. In one example, FIG. 4 shows a cross-sectional view between I-I in FIG. 3.

Referring to FIG. 4, the circuit film may include the first input pad 152a and the second input pad 152b formed in a top surface of the input side bonding area. The first input pad 152a and the second input pad 152b may be respectively connected to the first output pad 162a and the second output pad 162b formed in a bottom surface of the output side bonding area via vias and wirings.

The circuit film may include a plurality of first inspection pads 181 and a plurality of second inspection pads 182 used to inspect a bonding state at a bottom surface of a cut area CA that is cut at the time of shipment. The first inspection pad 181 may be electrically connected to the first input pad 152a and the first output pad 162a through vias and wirings. The second inspection pad 182 may be electrically connected to the second input pad 152b and the second output pad 162b via other vias and wirings.

A test signal may be applied via the first input pad 152a and the second input pad 152b. Whether the output signal is normally output through the first inspection pad 181 and the second inspection pad 182 may be determined to inspect the bonding state of the circuit film. The first inspection pad 181 and the second inspection pad 182 may be cut and removed along with the cut area CA to be cut at the time of shipment.

In one example, for inspection of the circuit film, the input pads may extend outside the circuit film, and the inspection signal may be applied to the input pads. Then, whether the output signal is output normally through the first inspection pad 181 and the second inspection pad 182 connected to the input pads via the vias and the wirings may be checked. A cut area CA of the input pads extending outside the circuit film may be removed at the time of shipment.

FIG. 5 is a cross-sectional view of the other side of the circuit film in a display device according to an embodiment of the present disclosure. In one example, FIG. 5 shows a cross-sectional view between II-II in FIG. 3.

Referring to FIG. 5, the circuit film may include the third input pad 151 formed in a top surface of the input side bonding area, and the third output pad 161a and the fourth output pad 161b respectively formed in two rows and formed at a bottom surface of the output side bonding area. The third input pad 151 may be connected to the source driver SDIC via the wiring, and the third output pad 161a and the fourth output pad 161b may be connected to the source driver SDIC through respective vias and wirings.

The circuit film may include the first inspection pad 181 and the second inspection pad 182 used to inspect the bonding state at the bottom surface of a cut area CA that is cut in the shipment. The first inspection pad 181 may be electrically connected to the third output pad 161a and the source driver SDIC through wirings and vias. The second inspection pad 182 may be electrically connected to the fourth output pad 161b and the source driver SDIC via other wirings and vias.

The test signal is applied via the third input pad 151. Whether the output signal is normally output through the first inspection pad 181 and the second inspection pad 182 may be checked to determine a bonding state of the circuit film and a connection state of the source driver SDIC.

In one example, the test signal may be applied to the third input pad 151 for inspection of the circuit film. Whether the output signal is normally output through the first inspection pad 181 and the second inspection pad 182 electrically connected to the output pads and the source driver SDIC through the wirings and the vias may be checked to determine a bonding state of the circuit film and a connection state of the source driver SDIC. After inspection of the circuit film, the cut area CA including the first inspection pad 181 and the second inspection pad 182 may be removed.

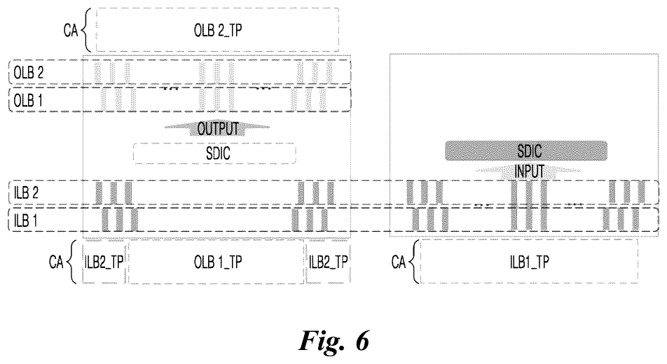

FIG. 6 shows a bottom view and a top view for inspection of a bonding state of a circuit film in a display device according to an embodiment of the present disclosure.

Referring to FIG. 6, the circuit film may include a first test pin ILB1_TP, a second test pin ILB2_TP, a third test pin OLB1_TP, and a fourth test pin OLB2_TP in the cut area CA to be cut. This test pin may be at least one of the plurality of first inspection pads 181 and the plurality of second inspection pads 182.

When inspecting the circuit film, an external test device (not shown) may apply a test signal to the first row ILB1 of the input side bonding area of the circuit film COF via the first test pin ILB1_TP for signal input corresponding to the first row ILB1 to perform the inspection. In this regard, the first test pin ILB1_TP for signal input corresponding to the first row ILB1 of the input side bonding area may be disposed in the cut area CA of the circuit film and may be removed after the inspection.

Furthermore, when inspecting the circuit film, the test device may inspect the condition of the circuit film based on a detecting result of the output signal through the third test pin OLB1_TP for signal output inspection corresponding to the first row OLB1 of the output side bonding area of the circuit film. In this regard, the third test pin OLB1_TP for signal output inspection corresponding to the first row OLB1 may be disposed in the cut area CA of the circuit film and may be removed after inspection.

Furthermore, in the inspection of the circuit film, the test device may apply a test signal to the second row ILB2 of the input side bonding area of the circuit film via the second test pin ILB2_TP for signal input corresponding to the second row ILB2 of the input side bonding area of the circuit film COF to conduct the inspection. In this regard, the second test pin ILB2_TP for signal input corresponding to the second row ILB2 of the input side bonding area may be disposed in the cut area CA of the circuit film and may be removed after inspection.

Furthermore, in inspecting the circuit film, the test device may inspect the state of the circuit film based on a detecting result of the output signal through the fourth test pin OLB2_TP for signal output inspection corresponding to the second row OLB2 on the output side bonding area of the circuit film. In this regard, the fourth test pin OLB2_TP for signal output inspection corresponding to the second row OLB1 of the output side bonding area may be disposed in the cut area CA of the circuit film and may be removed after inspection.

In this way, the input side bonding area of the circuit film may include the plurality of input pads, wherein ones of the plurality of input pads directly connected to the output pads of the output side bonding area other than the input pads connected to the source driver SDIC are arranged in the two rows. The test pins may be configured to enable inspection of the input and output pads arranged in the two rows. In this way, the state of the circuit film may be inspected.

A display device according to some aspects and embodiments of the present disclosure may be configured as follows.

A first aspect of the present disclosure may provide a display device comprising: a display panel; a printed circuit board; and a circuit film disposed between and connected to the display panel and the printed circuit board, wherein the circuit film includes an input side bonding area connected to the printed circuit board and an output side bonding area connected to the display panel, wherein the input side bonding area includes a plurality of input pads connected to the output side bonding area, wherein the plurality of input pads are arranged in two rows.

In accordance with some embodiments of the first aspect, the output side bonding area includes a plurality of output pads, wherein the plurality of output pads are arranged in two rows.

In accordance with some embodiments of the first aspect, the plurality of input pads of the input side bonding area of the circuit film includes: first input pads respectively disposed in both opposing sides of the input side bonding area and arranged in a first row; second input pads respectively disposed in both opposing sides of the input side bonding area and arranged in a second row; and third input pads disposed in a center of the input side bonding area and arranged in the first row, the second row or a single row as a combination of the first and second rows.

In accordance with some embodiments of the first aspect, each of the first input pad and the second input pad is bonded to a pad of the printed circuit board and is directly connected to the output side bonding area.

In accordance with some embodiments of the first aspect, a plurality of voltages and a plurality of control signals from the printed circuit board are applied to the first input pad and the second input pad.

In accordance with some embodiments of the first aspect, the third input pad is bonded to a pad of the printed circuit board and is connected to the output side bonding area through a source driver mounted on a center of the circuit film.

In accordance with some embodiments of the first aspect, the third input pad receives a digital signal from the printed circuit board.

In accordance with some embodiments of the first aspect, the output side bonding area of the circuit film includes: first output pads respectively disposed in both opposing sides of the output side bonding area and arranged in a first row; second output pads respectively disposed in both opposing sides of the output side bonding area and arranged in a second row; third output pads arranged in the first row and disposed in a center of the output side bonding area; and fourth output pads arranged in the second row and disposed in the center of the output side bonding area.

In accordance with some embodiments of the first aspect, each of the first output pad and the second output pad is bonded to the pad of the display panel and is directly connected to the input side bonding area.

In accordance with some embodiments of the first aspect, the third output pad and the fourth output pad are bonded to a pad of the display panel and are connected to the input side bonding area through a source driver mounted on the center of the circuit film.

In accordance with some embodiments of the first aspect, the first input pad and the second input pad are arranged in a staggered manner based on a reference line, the first output pad and the second output pad are arranged in a staggered manner based on the reference line, and the third input pad, the third output pad and the fourth output pad are arranged in the same column.

In accordance with some embodiments of the first aspect, the first input pad and the second input pad are located in different layers and in the same column, and the first output pad and the second output pad are located in different layers and in the same column.

A second aspect of the present disclosure may provide a display device comprising: a printed circuit board including a pad for outputting a plurality of voltages and a plurality of control signals; a display panel including a display area and a non-display area around the display area, wherein a plurality of sub-pixels are disposed in the display area, and a pad is disposed in the non-display area; a circuit film including an input side bonding area bonded to the pad of the printed circuit board and an output side bonding area bonded to the pad of the display panel, wherein the input side bonding area includes a plurality of input pads, wherein at least two of the plurality of input pads are respectively disposed in at least two rows; and a source driver mounted on the circuit film, wherein the source driver is electrically connected to the printed circuit board via the input side bonding area, and is electrically connected to the display panel via the output side bonding area.

In accordance with some embodiments of the second aspect, the output side bonding area of the circuit film includes a plurality of output pads arranged in two rows.

In accordance with some embodiments of the second aspect, the input side bonding area includes: first input pads arranged in a first row; second input pads arranged in a second row; and third input pads arranged in the first row, the second row or a single row as a combination of the first and second rows.

In accordance with some embodiments of the second aspect, the first input pads are respectively disposed in both opposing sides of the input side bonding area, wherein the second input pads are respectively disposed in both opposing sides of the input side bonding area, wherein the third input pads are disposed in a center of the input side bonding area.

In accordance with some embodiments of the second aspect, each of the first input pad and the second input pad is directly connected to the output side bonding area of the circuit film via each connection wiring, and the third input pad is connected to the output side bonding area of the circuit film via the source driver.

In accordance with some embodiments of the second aspect, the output side bonding area includes: first output pads arranged in a first row; second output pads arranged in a second row; third output pads arranged in the first row; and fourth output pads arranged in the second row.

In accordance with some embodiments of the second aspect, the first output pads are respectively disposed in both opposing sides of the output side bonding area, wherein the second output pads are respectively disposed in both opposing sides of the output side bonding area, wherein the third output pads are disposed in a center of the output side bonding area, wherein the fourth output pads are disposed in the center of the output side bonding area.

In accordance with some embodiments of the second aspect, the first input pad and the second input pad are arranged in a staggered manner based on a reference line, the first output pad and the second output pad are arranged in a staggered manner based on the reference line, and the third input pad, the third output pad and the fourth output pad are arranged in the same column.

According to embodiments of the present disclosure, the input and output pads directly connected to each other among the bonding pads of the circuit film are arranged in two rows to increase the gap size between the bonding pads, thereby realizing the display device that requires high-resolution and high-frequency display.

Furthermore, according to embodiments of the present disclosure, the gap between bonding pads may be increased without increasing a width of the circuit film.

Furthermore, according to embodiments of the present disclosure, an image quality in high-resolution and high-frequency display may be improved by increasing the gap between the bonding pads to reduce the interference therebetween.

Furthermore, according to embodiments of the present disclosure, the spacing between the bonding pads may be increased, thereby improving process capability.

According to embodiments of the present disclosure, production energy may be reduced by optimizing a process.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or characteristics of the present disclosure. Therefore, it should be appreciated that the embodiments as described above is not restrictive but illustrative in all respects.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display panel;
a printed circuit board; and
a circuit film disposed between and connected to the display panel and the printed circuit board, wherein the circuit film includes an input side bonding area connected to the printed circuit board and an output side bonding area connected to the display panel,
wherein the input side bonding area includes a plurality of input pads connected to the output side bonding area,
wherein the plurality of input pads are arranged in two rows.

2. The display device of claim 1, wherein the output side bonding area includes a plurality of output pads, wherein the plurality of output pads are arranged in two rows.

3. The display device of claim 2, wherein the plurality of input pads of the input side bonding area of the circuit film includes:
first input pads respectively disposed in both opposing sides of the input side bonding area and arranged in a first row;
second input pads respectively disposed in both opposing sides of the input side bonding area and arranged in a second row; and
third input pads disposed in a center of the input side bonding area, and arranged in the first row, the second row or a single row as a combination of the first and second rows.

4. The display device of claim 3, wherein each of the first input pad and the second input pad is bonded to a pad of the printed circuit board and is directly connected to the output side bonding area.

5. The display device of claim 4, wherein the first input pad and the second input pad are configured to receive a plurality of voltages and a plurality of control signals from the printed circuit board.

6. The display device of claim 3, wherein the third input pad is bonded to a pad of the printed circuit board and is connected to the output side bonding area through a source driver mounted on a center of the circuit film.

7. The display device of claim 6, wherein the third input pad is configured to receive a digital signal from the printed circuit board.

8. The display device of claim 3, wherein the output side bonding area of the circuit film includes:
first output pads respectively disposed in two opposing sides of the output side bonding area and arranged in a first row;
second output pads respectively disposed in two opposing sides of the output side bonding area and arranged in a second row;
third output pads arranged in the first row and disposed in a center of the output side bonding area; and
fourth output pads arranged in the second row and disposed in the center of the output side bonding area.

9. The display device of claim 8, wherein each of the first output pad and the second output pad is bonded to the pad of the display panel and is directly connected to the input side bonding area.

10. The display device of claim 8, wherein the third output pad and the fourth output pad are bonded to a pad of the display panel and are connected to the input side bonding area through a source driver mounted on a center of the circuit film.

11. The display device of claim 8, wherein the first input pad and the second input pad are arranged in a staggered manner based on a reference line, the first output pad and the second output pad are arranged in a staggered manner based on the reference line, and the third input pad, the third output pad and the fourth output pad are arranged in a same column.

12. The display device of claim 8, wherein the first input pad and the second input pad are located in different layers and in a same column, and the first output pad and the second output pad are located in different layers and in a same column.

13. A display device comprising:
a printed circuit board including a pad for outputting a plurality of voltages and a plurality of control signals;
a display panel including a display area and a non-display area around the display area, wherein a plurality of sub-pixels are disposed in the display area, and a pad is disposed in the non-display area;
a circuit film including an input side bonding area bonded to the pad of the printed circuit board and an output side bonding area bonded to the pad of the display panel, wherein the input side bonding area includes a plurality of input pads, wherein at least two of the plurality of input pads are respectively disposed in at least two rows; and
a source driver mounted on the circuit film, wherein the source driver is electrically connected to the printed circuit board via the input side bonding area, and is electrically connected to the display panel via the output side bonding area.

14. The display device of claim 13, wherein the output side bonding area of the circuit film includes a plurality of output pads arranged in two rows.

15. The display device of claim 14, wherein the input side bonding area includes:
first input pads arranged in a first row;
second input pads arranged in a second row; and
third input pads arranged in the first row, the second row or a single row as a combination of the first and second rows.

16. The display device of claim 15, wherein the first input pads are respectively disposed in two opposing sides of the input side bonding area,
wherein the second input pads are respectively disposed in two opposing sides of the input side bonding area,
wherein the third input pads are disposed in a center of the input side bonding area.

17. The display device of claim 16, wherein each of the first input pad and the second input pad is directly connected to the output side bonding area of the circuit film via each connection wiring, and the third input pad is connected to the output side bonding area of the circuit film via the source driver.

18. The display device of claim 15, wherein the output side bonding area includes:
first output pads arranged in a first row;
second output pads arranged in a second row;
third output pads arranged in the first row; and
fourth output pads arranged in the second row.

19. The display device of claim 18, wherein the first output pads are respectively disposed in two opposing sides of the output side bonding area,
wherein the second output pads are respectively disposed in two opposing sides of the output side bonding area,
wherein the third output pads are disposed in a center of the output side bonding area,
wherein the fourth output pads are disposed in the center of the output side bonding area.

20. The display device of claim 18, wherein the first input pad and the second input pad are arranged in a staggered manner based on a reference line, the first output pad and the second output pad are arranged in a staggered manner based on the reference line, and the third input pad, the third output pad and the fourth output pad are arranged in the same column.
